(19) United States
(12) Patent Application Publication
(10) Pub. No.: US 2024/0206066 A1
(43) Pub. Date: Jun. 20, 2024

(54) HYBRID CIRCUIT BOARD DEVICE TO SUPPORT CIRCUIT REUSE AND METHOD OF MANUFACTURE

(71) Applicant: QUALCOMM Incorporated, San Diego, CA (US)

(72) Inventors: Christopher Kong Yee Chun, Austin, TX (US); Mid Deng, Carlsbad, CA (US); John Eaton, San Diego, CA (US)

(21) Appl. No.: 18/069,004

(22) Filed: Dec. 20, 2022

(51) Int. Cl. H05K 1/14; H01R 12/71; H05K 3/34; H05K 3/36

(52) U.S. Cl. CPC H05K 1/141; H01R 12/714; H05K 3/3442; H05K 3/368

(57) ABSTRACT

A hybrid circuit board device includes a hybrid circuit board with a second, child circuit board disposed into a recessed circuit board portion of a first, parent circuit board to combine functionality of the child circuit board and the parent circuit board without exceeding a maximum circuit board height. The parent circuit board includes a first circuit board portion having a first thickness in a thickness direction. First interconnects on the first circuit board portion can couple to a first IC component. The child circuit board includes second interconnects to couple a second IC component. The child circuit board is in the recessed circuit board portion and is coupled to the parent circuit board by at least one board interconnect. The recessed circuit board portion of the parent circuit board has a second thickness that is thinner, in the thickness direction, than the first thickness.

### BACKGROUND

### I. Field of the Disclosure

The technology of the disclosure relates generally to circuit boards employed in electronic devices, such as laptop computers.

### II. Background

Electronic devices of various sizes and form factors provide high-performance computing capabilities and may have several wired and wireless interfaces. Certain capabilities and functions are common to many devices regardless of their types and sizes. For example, one manufacturer may produce mobile handheld devices and personal computers that share some identical functionalities, but these are obviously very different packages. Using the same circuitry in both devices seems like a cost-effective option, but the limitations imposed by the different sizes and costs of the respective devices can make such sharing impossible or impractical. For example, a circuit designed for a larger device, such as a laptop computer, can be made more cheaply than a circuit for a same or similar function in a smaller device, but the circuits designed for laptops cannot fit into cellular telephones. The technology of much smaller circuits designed for a cellular telephone would fit into a laptop, but the technology used for cellular telephones may be too expensive to use in a laptop computer. In addition, known suitable components from other manufacturers may be unavailable for use by product designers due to technology incompatibilities.

### SUMMARY

Aspects disclosed herein include a hybrid circuit board device to support circuit reuse. Methods for fabricating a hybrid circuit board device are also disclosed. An exemplary hybrid circuit board device includes a hybrid circuit board in which a second, child circuit board is disposed into a recessed circuit board portion of a first, parent circuit board to combine the functionality of the child circuit board and the parent circuit board without exceeding a maximum circuit board height. The parent circuit board includes a first circuit board portion having a first thickness in a thickness direction through the first circuit board portion. First interconnects of a first interconnect type disposed on the first circuit board portion are configured to couple a first integrated circuit (IC) component to a first circuit. The child circuit board includes second interconnects of a second interconnect type configured to couple a second IC component to a second circuit. The child circuit board is disposed in the recessed circuit board portion of the parent circuit board and is coupled to the parent circuit board by at least one board interconnect. The recessed circuit board portion of the parent circuit board has a second thickness that is thinner, in the thickness direction, than the first thickness. In this manner, a hybrid circuit board device providing IC component interconnects of a first type can incorporate one or more ICs having a different second type of interconnects on a child circuit board without exceeding a maximum circuit board height.

For example, a recessed surface of the recessed circuit board portion may be recessed (e.g., below), in the thickness direction, from a first surface of the first circuit board portion. In some examples, a combined thickness in the thickness direction of a third thickness of the child circuit board and the second thickness of the recessed circuit board portion is less than the first thickness of the first circuit board portion. Even if the second interconnects of the second interconnect type on the second surface are disposed at a different center-to-center pitch than the first interconnects of the first interconnect type on the first surface, a second IC component may be incorporated in a hybrid circuit board device without exceeding the maximum circuit board height.

In this regard, in one aspect, a hybrid circuit board device comprising a hybrid circuit board is disclosed. The hybrid circuit board includes a first circuit board comprising a first circuit board portion having a first thickness in a thickness direction and comprising first interconnects configured to couple to a first IC component. The first circuit board also includes a recessed circuit board portion having a second thickness thinner than the first thickness in the thickness direction. The hybrid circuit board further includes a second circuit board having a third thickness in the thickness direction and disposed on the recessed circuit board portion, the second circuit board comprising second interconnects configured to couple to a second IC component. The hybrid circuit board further includes at least one board interconnect coupling the second circuit board to the recessed circuit board portion of the first circuit board.

In another exemplary aspect, a method of fabricating a hybrid circuit board device comprising a hybrid circuit board is disclosed. The method comprises forming a hybrid circuit board. The hybrid circuit board includes a first circuit board comprising a first circuit board portion having a first thickness in a thickness direction and comprising first interconnects configured to couple to a first IC component. The first circuit board also includes a recessed circuit board portion having a second thickness thinner than the first thickness in the thickness direction. The hybrid circuit board further includes a second circuit board having a third thickness in the thickness direction and disposed on the recessed circuit board portion, the second circuit board comprising second interconnects configured to couple to a second IC component. The hybrid circuit board further includes at least one board interconnect coupling the second circuit board to the recessed circuit board portion of the first circuit board.

### BRIEF DESCRIPTION OF THE DRAWINGS

FIG. 1 is a three-dimensional (3D) perspective view of an exemplary hybrid circuit board device, including a hybrid circuit board in which a child circuit board coupled to a second integrated circuit (IC) component with interconnects of a second interconnect type is disposed into a recessed circuit board portion of a parent circuit board coupled to a first IC component with interconnects of a first interconnect type;

FIG. 2A is a cross-sectional side view of a hybrid circuit board device with a child circuit board positioned above a recessed circuit board portion of the parent circuit board;

FIG. 2B is a cross-sectional side view of the hybrid circuit board device in FIG. 2A with a child circuit board disposed in the recessed circuit board portion of the parent circuit board;

FIG. 3 is a flowchart of an exemplary method of fabricating the hybrid circuit board device in FIG. 1;

FIG. 4 is a cross-sectional side view of a hybrid circuit board device, including a hybrid circuit board with a first board interconnect coupling a child circuit board to a recessed circuit board portion of a parent circuit board;

FIG. 5 is a 3D perspective view of a parent circuit board, including recessed circuit board portions in which the shoulder boundaries have different numbers of linear boundary sections on which child circuit boards may be coupled in an overlapping region;

FIG. 6 is a cross-sectional side view of another hybrid circuit board device, in which a child circuit board is coupled to the recessed circuit board region by a second board interconnect;

FIG. 7 is a cross-sectional side view of another hybrid circuit board device, including a child circuit board coupled to the recessed circuit board region by a third board interconnect;

FIG. 8 is a block diagram of an exemplary processor-based system that can include a hybrid circuit board device including a hybrid circuit board in which a child circuit board is disposed in a recessed circuit board portion of a parent circuit board to accommodate an interconnect mismatch while continuing to meet circuit board height requirements as shown in FIGS. 1, 2A, 2B, 4, 6, and 7 and according to, but not limited to, any of the exemplary fabrication processes in FIG. 3; and

FIG. 9 is a block diagram of an exemplary wireless communication device that includes radio-frequency (RF) components that can include a hybrid circuit board device including a hybrid circuit board in which a child circuit board is disposed in a recessed circuit board portion of a parent circuit board to accommodate an interconnect mismatch while continuing to meet circuit board height requirements as shown in FIGS. 1, 2A, 2B, 4, 6, and 7 and according to, but not limited to, any of the exemplary fabrication processes in FIG. 3.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed herein include a hybrid circuit board device to support circuit reuse. Methods for fabricating a hybrid circuit board device are also disclosed. An exemplary hybrid circuit board device includes a hybrid circuit board in which a second, child circuit board is disposed into a recessed circuit board portion of a first, parent circuit board to combine the functionality of the child circuit board and the parent circuit board without exceeding a maximum circuit board height. The parent circuit board includes a first circuit board portion having a first thickness in a thickness direction through the first circuit board portion. First interconnects of a first interconnect type disposed on the first circuit board portion are configured to couple a first integrated circuit (IC) component to a first circuit. The child circuit board includes second interconnects of a second interconnect type configured to couple a second IC component to a second circuit. The recessed circuit board portion of the parent circuit board has a second thickness that is thinner, in the thickness direction, than the first thickness. The child circuit board is disposed in the recessed circuit board portion of the parent circuit board and is coupled to the parent circuit board by at least one board interconnect. In this manner, a hybrid circuit board device providing IC component interconnects of a first type can incorporate one or more ICs having a different second type of interconnects on a child circuit board without exceeding a maximum circuit board height.

For example, a recessed surface of the recessed circuit board portion may be recessed (e.g., below), in the thickness direction, from a first surface of the first circuit board portion. In some examples, a combined thickness in the thickness direction of a third thickness of the child circuit board and the second thickness of the recessed circuit board portion is less than the first thickness of the first circuit board portion. Even if the second interconnects of the second interconnect type on the second surface are disposed at a different center-to-center pitch than the first interconnects of the first interconnect type on the first surface, a second IC component may be incorporated in a hybrid circuit board device without exceeding the maximum circuit board height.

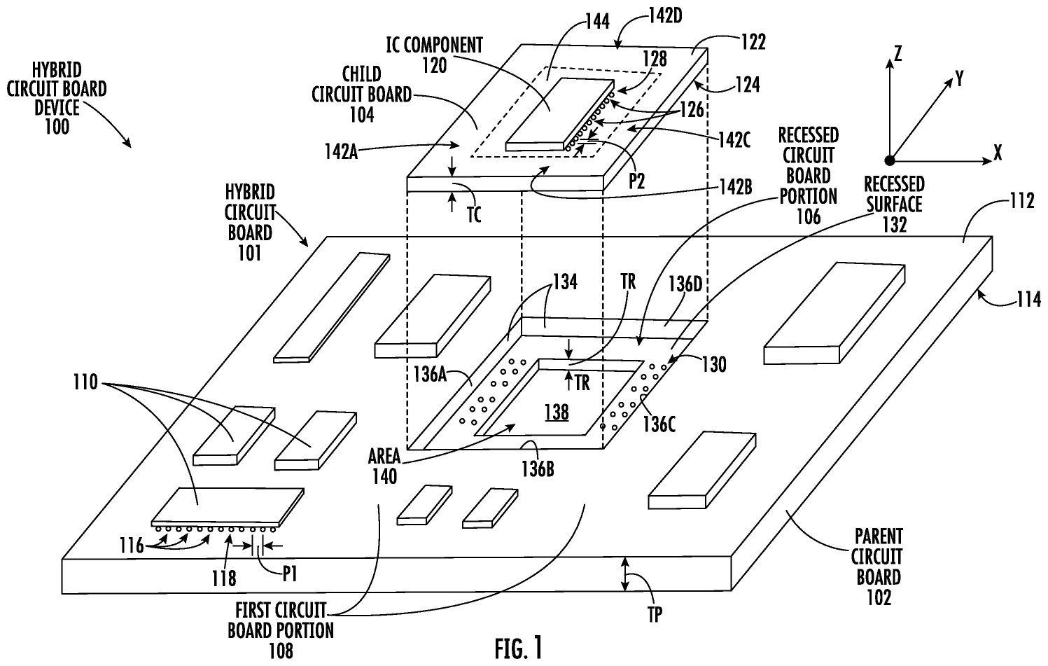

FIG. 1 is a three-dimensional (3D) perspective view of a first example of an exemplary hybrid circuit board device 100, including a hybrid circuit board 101. The hybrid circuit board 101 includes a first circuit board 102 and a second circuit board 104. The second circuit board 104 is disposed in a recessed circuit board portion 106 of the first circuit board 102. In this regard, the first circuit board 102 is also referred to herein as a parent circuit board 102, and the second circuit board 104 is referred to herein as a child circuit board 104 because the child circuit board 104 is subordinate to and supported by the parent circuit board 102.

The recessed circuit board portion 106 of the parent circuit board 102 is thinner than a first circuit board portion 108. The thinner recessed circuit board portion 106 allows the child circuit board 104 to be positioned in (e.g., recessed into) the parent circuit board 102 without causing the resulting hybrid circuit board 101 to exceed a maximum circuit board height. In some examples, the hybrid circuit board 101 may not be thicker than the parent circuit board 102, with the child circuit board 104 disposed in the recessed circuit board portion 106. The parent circuit board 102 and the child circuit board 104 may be printed circuit boards (PCBs).

In some examples, the parent circuit board 102 may be of a size and/or type employed in laptop computers, desktop computers, tablets, or other electronic devices having comparable dimensions. The hybrid circuit board device 100 may include a plurality of integrated circuit (IC) components 110 coupled to a front side surface 112 and/or to a back side surface 114 of the parent circuit board 102. The parent circuit board 102 includes first interconnects 116, which are of a first interconnect type 118, to couple the IC components 110 to the first circuit board portion 108. The first interconnects 116 couple the IC components 110 electrically to the parent circuit board 102 and may also mechanically couple the IC components 110 to the parent circuit board 102.

The hybrid circuit board device 100 may include one or more IC components 120 coupled to a front side surface 122 of the child circuit board 104. In some examples, one or more of the IC components 120 may also or alternatively be coupled to a back side surface 124 of the child circuit board 104. The child circuit board 104 includes second interconnects 126, which are of a second interconnect type 128, to couple the IC components 120 to the child circuit board 104. The second interconnects 126 couple the IC components 120 electrically to the parent circuit board 102 and may also mechanically couple the IC components 120 to the child circuit board 104.

In some examples, the IC component 120 in FIG. 1 may provide a function or capability that is common to many types of electronic devices, such as laptop computers, tablets, and/or handheld mobile telephones. Thus, the second type interconnects 128 of the IC component 120 may be well-known for use in various applications but still not compatible with technologies employed in all types of electronic devices. The first interconnect type 118 of the first interconnects 116 and the second interconnect type 128 of the second interconnects 126 may be the same in some examples of the hybrid circuit board 101, while in other examples, they may be different. The first and second interconnect types 118 and 128 may be considered different types if they have different mechanical configurations, structures, materials, and/or dimensions. One such dimension is center-to-center pitch.

In this context, an “IC component” refers to any IC die comprising active semiconductor transistors, semiconductor devices, and/or passive circuit elements. The IC components 110 and 120 may include various components, including general-purpose processors, graphics processors, systems-on-chip (SOCs), memories, RF circuits, and/or acoustic devices, for example. The term “component,” as used herein, may also include IC components as described above.

Applications of the hybrid circuit board 101 may be better understood in view of the following aspects.

In a first aspect, electronic devices come in many sizes and forms. The physical size of an electronic device can limit the sizes of IC components that will fit therein. Handheld devices are a well-known example of an electronic device that has been significantly reduced in size over time while more functionality has been added, while the physical sizes of other electronic devices have changed little, if at all. Thus, components may be manufactured in different technologies according to the cost point and physical limitations of different types of devices. Generally, reducing the size of a component without reducing function requires more advanced and expensive technology. Larger and cheaper technologies may be employed in larger devices where space is less restrictive. Obviously, larger components will not fit into a smaller device, but smaller IC components can fit into a larger device. However, the cost of using a smaller IC component in a larger device may unnecessarily increase the cost of the larger device. This cost increase may be due to the increased cost of the smaller component itself and the costs of other parts that must have compatible technology.

For example, where a predetermined number of interconnects (e.g., for inputs, outputs, power, and ground) are needed to implement a particular function and an IC component for that function is made smaller (e.g., to fit into a cell phone), the interconnects may need to be more densely arranged. Since the interconnects on a circuit board must be compatible with those of the IC component, and denser interconnects are more expensive, the cost of the circuit board would also increase to accommodate components having denser interconnects.

In a second aspect, many IC components are required to meet certain industry standards, such as power, noise, or timing requirements. A package containing one of such components may be required to pass a rigid certification process. Once the package is certified, there may be no further need for certification of electronic devices in which the circuit board and IC component are employed. Further to this example, a child circuit board 104, including an IC component 120, may be separately certified and included in the hybrid circuit board device 100 without the need for additional certification.

The hybrid circuit board device 100 may be employed to incorporate a smaller, higher technology IC component into a larger electronic device according to the first aspect above. According to the second aspect above, the hybrid circuit board device 100 may incorporate an approved, verified, and/or certified vendor package as the child circuit board 104 with the IC component 120. The hybrid circuit board device 100 may also be employed in other aspects.

As discussed above, the second interconnect type 128 of the second interconnects 126 of the IC components 120 may be different than the first interconnect type 118 of the first interconnects 116 of the IC components 110. For example, the first interconnects 116 may be plated through-hole (PTH) interconnects, and the second interconnects 126 may be high-density interconnects (HDI), as known in the industry. As another example, the first interconnect type 118 and the second interconnect type 128 may be similar but from different generations of a technology, such that dimensions are different. For these or other reasons, the first interconnects 116 may have a first center-to-center pitch P1 (“pitch P1”), while the second interconnects 126 have a second center-to-center pitch P2 (“pitch P2”). The pitch P2 may be the same or different than the pitch P1, depending on the technologies employed in the parent circuit board 102 and the child circuit board 104. For example, HDI-type interconnects may comprise arrays of solder balls with a center-to-center pitch range of 0.30 to 0.40 millimeters (mm). The PTH-type interconnects include through-holes with interior surfaces that are plated with a conductive material and have a center-to-center pitch in a range of 0.60 to 0.85 mm.

The hybrid circuit board 101 further includes board interconnects 130 to couple the child circuit board 104 to the parent circuit board 102. The child circuit board 104 may include various types of board interconnects 130, as described below. The board interconnects 130 are independent of the first interconnect type 118 and the second interconnect type 128. The board interconnects 130 may mechanically and/or electrically couple the child circuit board 104 to the parent circuit board 102. In this manner, a total cost of an electronic device (e.g., a laptop computer) may be reduced by a hybrid circuit board 101 that allows an existing IC component 120 having a second interconnect type 128, which may be manufactured for another type of electronic device (e.g., mobile telephone), to be incorporated into the parent circuit board 102. This would avoid the need to develop another IC component of a compatible technology or develop a system circuit board with a more expensive technology (i.e., interconnect types) that would be directly compatible with the IC component 120.

To address the aspects discussed above, it may be possible to couple (e.g., mount or affix) a separate child circuit board onto a top surface of (e.g., above) a parent circuit board that does not include a recessed circuit board portion, but the resulting combined thickness is more likely to exceed a circuit board height that is acceptable for the intended electronic device package. The recessed circuit board portion 106 of the parent circuit board 102 has a second thickness TR in a thickness direction (e.g., Z-axis direction in FIG. 1) that allows the child circuit board 104 to be recessed into a first thickness TP of the parent circuit board 102 without exceeding a circuit board height maximum. The first thickness TP also extends in the thickness direction (e.g., Z-axis direction in FIG. 1). In some examples, the second thickness TR is less than fifty percent (50%) of the first thickness TP. In the first circuit board portion 108, the parent circuit board 102 has the first thickness TP. The child circuit board 104 has a third thickness TC in the thickness direction. In some examples, a combined thickness of the second thickness TR of the recessed circuit board portion 106 and the third thickness TC of the child circuit board 104 is less than the first thickness TP of the first circuit board portion 108 of the parent circuit board 102. The recessed circuit board portion 106, having a second thickness TR that is thinner (e.g., smaller) than the first thickness TP of the first circuit board portion 108, provides space to include the child circuit board 104 into the parent circuit board 102 without simply stacking the child circuit board 104 on the first circuit board portion 108.

The recessed circuit board portion 106 provides support in areas where the child circuit board 104 overlaps the recessed circuit board portion 106. That is, the child circuit board 104 is supported where the back side surface 124 is facing (e.g., opposite to) and immediately adjacent to the recessed circuit board portion 106 in a direction orthogonal to the back side surface 124. The hybrid circuit board 101 includes at least one board interconnect 130 disposed on the recessed circuit board portion 106 between the back side surface 124 of the child circuit board 104 and a recessed surface 132 of the recessed circuit board portion 106 of the parent circuit board 102 to couple the child circuit board 104 to the parent circuit board 102.

In the example in FIG. 1, the parent circuit board 102 transitions between the second thickness TR of the recessed circuit board portion 106 and the first thickness TP of the first circuit board portion 108 at a shoulder boundary 134. Here, the shoulder boundary 134 is rectangular having first, second, third, and fourth linear boundary sections 136A-136D. In this regard, the first linear boundary section 136A and the second linear boundary section 136B may be orthogonal to each other (e.g., in a plane including the X-axis and the Y-axis), and the third linear boundary section 136C may also be orthogonal to the second linear boundary section 136B. The recessed surface 132 extends from the shoulder boundary 134 and provides support for the child circuit board 104.

In this example, the recessed circuit board portion 106 includes an opening 138 through the parent circuit board 102. The opening 138 may allow increased heat dissipation or may be created to provide space in which to accommodate one of the IC components 120 coupled to the back side surface 124 of the child circuit board 104 while the back side surface 124 of the child circuit board 104 is closely coupled to the recessed surface 132. The opening 138 extends through the parent circuit board 102 in a direction of the thickness TP (e.g., Z-axis direction). The opening 138 is through an area 140 of the recessed surface 132.

In this example, the child circuit board 104 has a rectangular shape corresponding to the rectangular shape of the shoulder boundary 134. The child circuit board 104 is smaller than the shoulder boundary 134, so the child circuit board 104 will fit into the recessed circuit board portion 106. The shoulder boundary 134 extends around the opening 138, and the child circuit board 104 is larger than the area 140 of the opening 138. Thus, the child circuit board 104 may be positioned to have overlapping edge portions 142A-142D disposed opposite to the recessed surface 132 on each of the linear boundary sections 136A-136D around a perimeter of the opening 138. The child circuit board 104 also includes a non-overlapping portion 144 disposed opposite to the opening 138. Thus, the non-overlapping portion 144 does not overlap the recessed surface 132. The board interconnects 130 are disposed on the recessed surface 132 between the recessed surface 132 and the overlapping edge portions 142A-142D of the back side surface 124. The recessed surface 132 of the recessed circuit board portion 106 and the back side surface 124 of the child circuit board 104 may each be planar surfaces and each orthogonal to the thickness direction (e.g., Z-axis direction). In such an example, the recessed surface 132 and the back side surface 124 extend in the X-axis direction and Y-axis direction. In some examples, one or both of the recessed surface 132 and the back side surface 124 may not be completely planar and/or may be non-orthogonal to the thickness direction.

The parent circuit board 102 and the child circuit board 104 may be printed circuit boards (PCBs). Accordingly, though not shown in FIG. 1, the parent circuit board 102 may include circuits in the first circuit board portion 108 for interconnecting the IC components 110 to each other through the first interconnects 116. The circuits may include one or more levels of metal interconnects in the parent circuit board 102 for routing signals between the board interconnects 130 and the first circuit board portion 108. Circuits in the first circuit board portion 108 may also include other passive and/or active components in addition to the IC components 110. The child circuit board 104 also includes circuits (not shown) to couple the one or more IC components 120 to each other and to the second interconnects 126. The parent circuit board 102 and the child circuit board 104 may each include power and ground planes (not shown).

It should be noted that in assembling the hybrid circuit board device 100, the IC components 110 may be attached to the first interconnects 116 before or after the child circuit board 104 is coupled to the recessed circuit board portion 106. Similarly, the IC components 120 may be attached to the second interconnects 126 before or after the child circuit board 104 is coupled to the recessed circuit board portion 106.

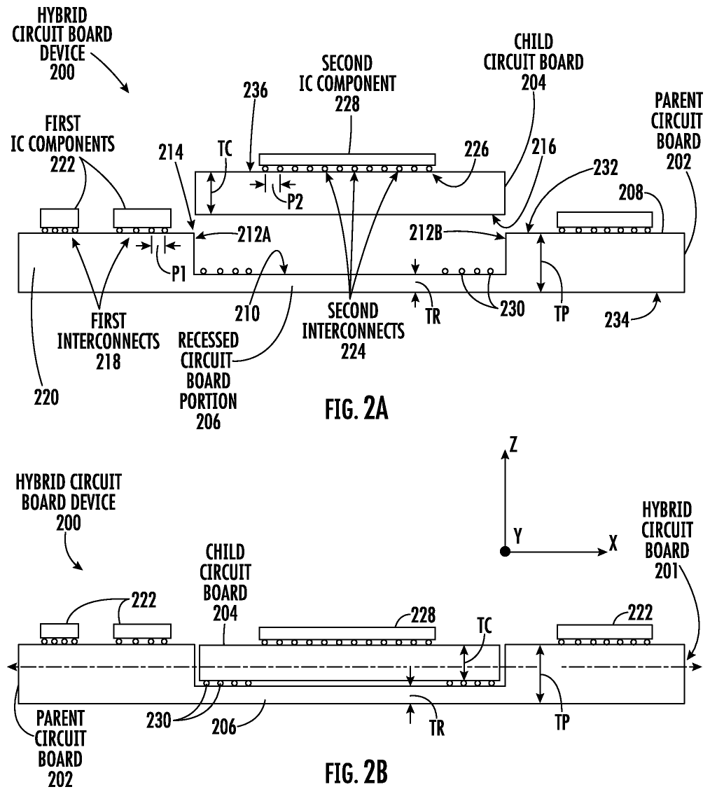

FIGS. 2A and 2B are cross-sectional side views of another example of a hybrid circuit board device 200, including a hybrid circuit board 201. The hybrid circuit board 201 further includes a first, parent circuit board 202, and a second, child circuit board 204. FIG. 2A shows the child circuit board 204 positioned above (in the Z-axis direction) a recessed circuit board portion 206 of the parent circuit board 202. FIG. 2B shows the child circuit board 204 positioned on and supported by the recessed circuit board portion 206. The recessed circuit board portion 206 of the parent circuit board 202 has a second thickness TR that is less than a first thickness TP of a first circuit board portion 208 of the parent circuit board 202. In some examples, the second thickness TR is less than fifty percent (50%) of the first thickness TP. The child circuit board 204 has a third thickness TC. In the example shown in FIG. 2B, a combined thickness of the third thickness TC of the child circuit board 204 and the second thickness TR of the recessed circuit board portion 206 may be less than or equal to the first thickness TP to ensure that the hybrid circuit board device 200 does not exceed a maximum circuit board height.

Unlike the hybrid circuit board device 100 in FIG. 1, the recessed circuit board portion 206 does not have an opening. Thus, a recessed surface 210 extends from a first linear boundary section 212A of a shoulder boundary 214 to a second linear boundary section 212B. In this example, all of a second back side surface 216 of the child circuit board 204 overlaps the recessed surface 210.

A significant aspect of the illustrations in FIGS. 2A and 2B are first interconnects 218 of a first interconnect type 220 coupling first IC components 222 to the parent circuit board 202, and second interconnects 224 of a second interconnect type 226 coupling second IC component 228 to the child circuit board 204. The first interconnects 218 are disposed at a first center-to-center pitch P1, and the second interconnects 224 are disposed at a second center-to-center pitch P2. In some examples, the center-to-center pitch P1 is the same as the center-to-center pitch P2. In other examples, the center-to-center pitch P2 may be smaller than or larger than the center-to-center pitch P1. In such examples, the second IC component 228 may have been originally designed to provide a particular function in a smaller (e.g., handheld) or larger electronic device and is included in the hybrid circuit board device 200 to reuse the second IC component 228 for the same particular function.

The hybrid circuit board 201 includes the parent circuit board 202, including the first circuit board portion 208 having the first thickness TP and comprising the first interconnects 218 configured to couple to the first IC components 222, and the recessed circuit board portion 206 having the second thickness TR that is thinner than the first thickness TP. The hybrid circuit board device 200 also includes the child circuit board 204, which is the third thickness TC and is disposed on the recessed circuit board portion 206. The child circuit board 204 includes the second interconnects 224 configured to couple to the second IC component 228. The hybrid circuit board 201 also includes at least one board interconnect 230 to couple the child circuit board 204 to the recessed circuit board portion 206 of the parent circuit board 202.

The first interconnects 218 are disposed on a first surface 232 of the first circuit board portion 208 of the parent circuit board 202. The parent circuit board 202 also has a first back side surface 234 opposite to the first surface 232. The first surface 232 and the first back side surface 234 are separated in the thickness direction by the first thickness TP, which is directed through the first circuit board portion 208. The second interconnects 224 are disposed on a second surface 236 of the child circuit board 204. The second back side surface 216 of the child circuit board 204 is opposite to the second surface 236. The second surface 236 and the second back side surface 216 are separated in the thickness direction through the child circuit board 204 (e.g., Z-axis direction) by the third thickness TC. The recessed circuit board portion 206 includes the recessed surface 210 opposite the first back side surface 234 of the parent circuit board 202. The recessed surface 210 and the first back side surface 234 are separated in the thickness direction by the second thickness TR. The second back side surface 216 of the child circuit board 204 and the recessed surface 210 are each orthogonal (or substantially orthogonal) to the thickness direction, and the second back side surface 216 overlaps the recessed surface 210 in the thickness direction. In the non-limiting example in FIGS. 2A and 2B, the first surface 232, the first back side surface 234, the second surface 236, the second back side surface 216, and the recessed surface 210 are planar surfaces in planes extending in the X-axis and Y-axis directions and the thickness direction is the Z-axis direction.

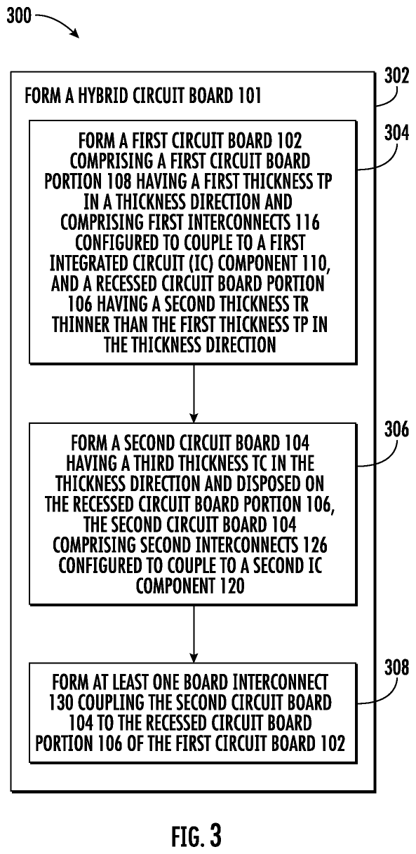

FIG. 3 is a flowchart of an exemplary method 300 for fabricating the hybrid circuit board device 100 in FIG. 1. The method 300 includes forming a hybrid circuit board 101 (block 302), comprising forming a first circuit board 102 comprising a first circuit board portion 108 having a first thickness TP in the thickness direction and comprising first interconnects 116 configured to couple to a first IC component 110, and a recessed circuit board portion 106 having a second thickness TR, thinner than the first thickness TP (block 304). Forming the hybrid circuit board 101 further comprises forming a second circuit board 104 having a third thickness TC in the thickness direction and disposed on the recessed circuit board portion 106, the second circuit board 104 comprising second interconnects 126 configured to couple to a second IC component 120 (block 306). Forming the hybrid circuit board 101 further comprises forming at least one board interconnect 130 coupling the second circuit board 104 to the recessed circuit board portion 106 of the first circuit board 102 (block 308).

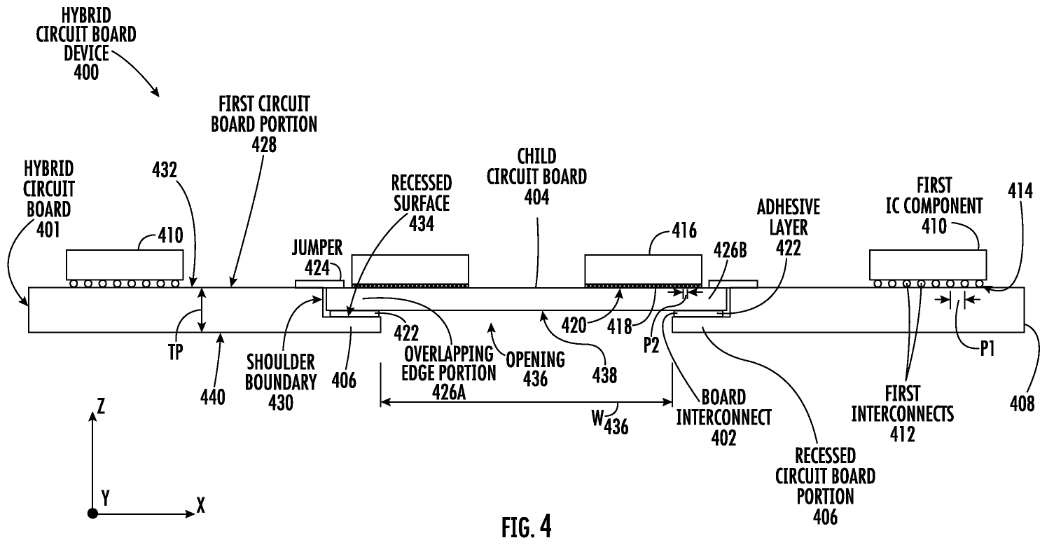

FIG. 4 is a cross-sectional side view of another example of a hybrid circuit board device 400, including a hybrid circuit board 401. The hybrid circuit board 401 includes a board interconnect 402 coupling a child circuit board 404 to a recessed circuit board portion 406 of a parent circuit board 408. The board interconnect 402 may mechanically couple, electrically couple, or both mechanically and electrically couple the child circuit board 404 to the recessed circuit board portion 406. FIG. 4 also shows the first IC components 410 coupled to the parent circuit board 408 by first interconnects 412 of a first interconnect type 414. Second IC components 416 are coupled to the child circuit board 404 by second interconnects 418, which are of a second interconnect type 420. In some examples, the first interconnect type 414 is the same as the second interconnect type 420. In some examples, the first interconnects 412 are disposed at a first center-to-center pitch P1 that is the same as a center-to-center pitch P2 of the second interconnects 418. In other examples, the first interconnect type 414 of the first interconnects 412 is different than the second interconnect type 420 of the second interconnects 418. In some examples, the first center-to-center pitch P1 may differ from the second center-to-center pitch P2. For example, the center-to-center pitch P1 may be larger or smaller than the center-to-center pitch P2. A relationship between the pitch P1 and the pitch P2 may be independent of whether the first interconnect type 414 is the same as the second interconnect type 420.

In the example in FIG. 4, the at least one board interconnect 402 comprises adhesive layer 422 between the child circuit board 404 and the recessed circuit board portion 406 of the parent circuit board 408, where the child circuit board 404 overlaps the recessed circuit board portion 406. The at least one board interconnect 402 may be a continuous adhesive layer 422 disposed around most or all of a perimeter (e.g., all four sides) of the rectangular child circuit board 404 or may be multiple separate adhesive layers 422. In this example, the adhesive layer(s) 422 provides a mechanical coupling of the child circuit board 404 to the parent circuit board 408 but not an electrical coupling. A combined thickness (e.g., total) of the second thickness TR of the recessed circuit board portion 406, the adhesive layer 422, and the third thickness TC of the child circuit board 404 may be less than or equal to a first thickness TP of the parent circuit board 408. In this example, the hybrid circuit board 401 includes jumpers 424 extending between overlapping edge portions 426A and 426B of the child circuit board 404 and the first circuit board portion 428 of the parent circuit board 408. The jumpers 424 may interconnect the first IC components 410 to the second IC components 416. The jumpers 424 may have a center-to-center pitch that is independent of the first interconnect type 414 and the second interconnect type 420. The jumpers 424 may be any appropriate type of connector independent of the first and second interconnect types 414 and 420.

As shown in FIG. 4, a shoulder boundary 430 extends in a Z-axis direction from a first surface 432 of the first circuit board portion 428 to a recessed surface 434 of the recessed circuit board portion 406. The recessed circuit board portion 406 extends in an X-axis direction from the shoulder boundary 430 to an opening 436. The parent circuit board 408 and opening 436 correspond in this respect to the parent circuit board 102 and opening 138 in FIG. 1. The recessed circuit board portion 406 extending in the X-axis direction, between the shoulder boundary 430 and the opening 436, has a width W₄₃₆ that may be determined as needed to ensure the recessed circuit board portion 406 provides appropriate support, interconnectivity, heat dissipation, structural integrity, and other considerations. The opening 436 extends in the thickness direction (Z-axis direction) through the recessed circuit board portion 406. In some examples, one or more of the second IC components 416 coupled to a second back side surface 438 of the child circuit board 404 may extend in the thickness direction into (e.g., through) the opening 436 and through a first back side surface 440 of the parent circuit board 408.

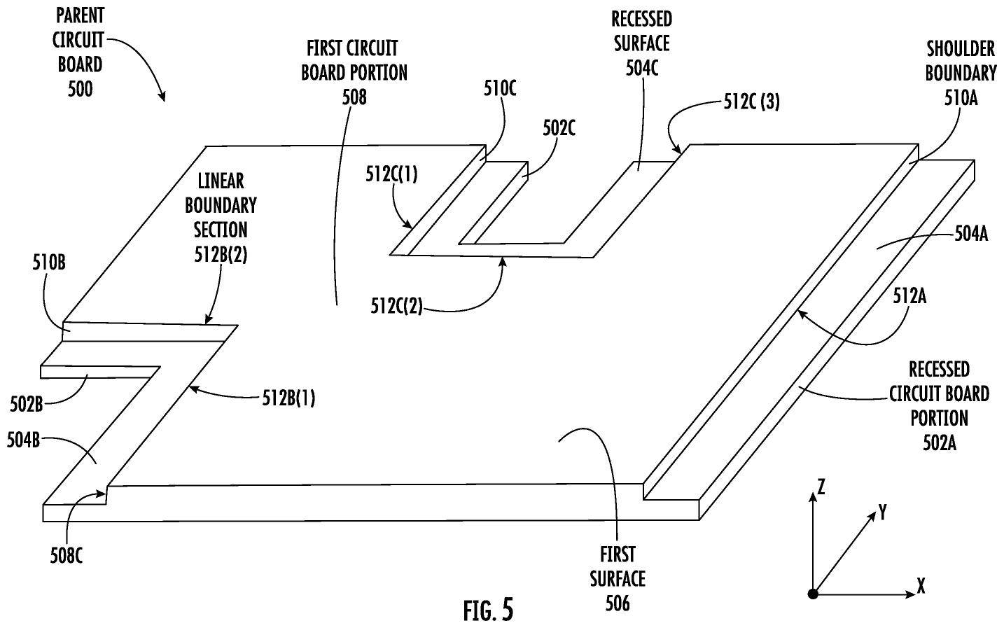

FIG. 5 is a 3D perspective view of a parent circuit board 500 that may be employed in a hybrid circuit board in a hybrid circuit board device corresponding to the hybrid circuit board devices shown in FIGS. 1, 2A, 2B, and 4. The parent circuit board 500 includes recessed circuit board portions 502A, 502B, and 502C with recessed surfaces 504A-504C, respectively. The recessed surfaces 504A-504C are recessed in the Z-axis direction from a first surface 506 of a first circuit board portion 508. The parent circuit board 500 transitions from the first surface 506 to the recessed surfaces 504A-504C at shoulder boundaries 510A-510C, respectively. The shoulder boundary 510A includes a linear boundary section 512A that extends (e.g., in the X-axis direction) from the shoulder boundary 510A. The shoulder boundary 510B includes linear boundary sections 512B(1) and 512B(2) that are orthogonal to each other. The shoulder boundary 510C includes linear boundary sections 512C(1)-512C(3), with linear boundary sections 512C(1) and 512C(3) both extending orthogonally from the linear boundary section 512C(2). Although no board interconnects are shown in FIG. 5, the parent circuit board 500 is configured to be mechanically and/or electrically coupled to child circuit boards (not shown) at the recessed surfaces 504A-504C of the recessed circuit board portions 502A-502C. The illustrated examples of shoulder boundaries shown in FIGS. 1, 2, 4, and 5 are linear boundary sections of and rectangular shapes corresponding to shapes of child circuit boards; however, the hybrid circuit boards disclosed herein are not limited to having shoulder boundaries only as shown and may include any appropriate shape corresponding to a child circuit board.

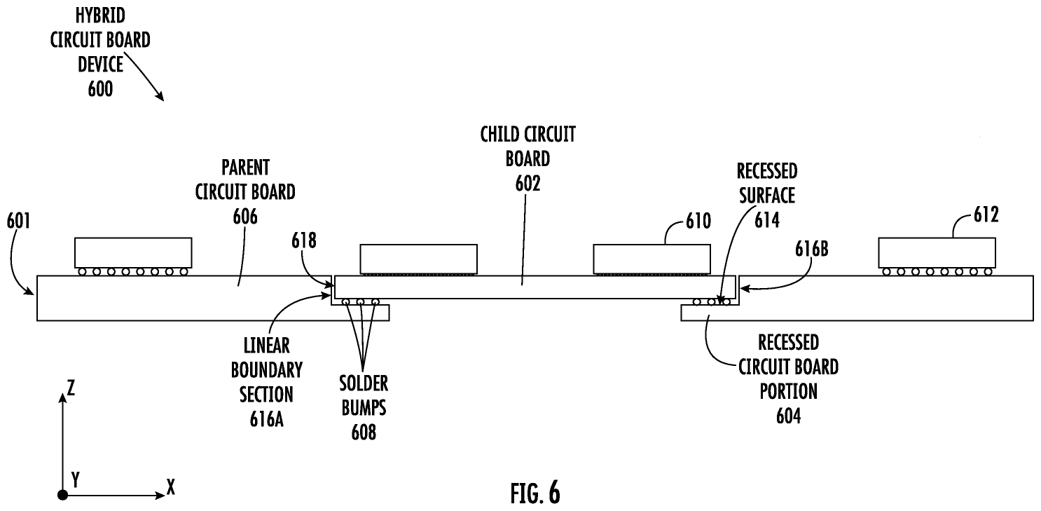

FIG. 6 is a cross-sectional side view of another hybrid circuit board device 600, including a hybrid circuit board 601, which includes a child circuit board 602 coupled to a recessed circuit board portion 604 of a parent circuit board 606 by way of solder bumps 608, in a second example of a board interconnect. The hybrid circuit board device 600 also includes a second IC component 610 coupled to the child circuit board 602 and a first IC component 612 coupled to the parent circuit board 606. The hybrid circuit board 601 includes the solder bumps 608 between the child circuit board 602 and the recessed circuit board portion 604. The solder bumps 608 mechanically couple the child circuit board 602 to the parent circuit board 606 and electrically couple the child circuit board 602 to the parent circuit board 606. The solder bumps 608 may provide an electrical coupling of the second IC component 610 on the child circuit board 602 to the first IC component 612 on the parent circuit board 606. The solder bumps 608 may alternatively be solder balls. The solder bumps 608 may be disposed in a ball grid array, including one or more rows of the solder bumps 608 on a recessed surface 614 of the recessed circuit board portion 604. The recessed surface 614 extends from linear boundary sections 616A and 616B of a shoulder boundary 618.

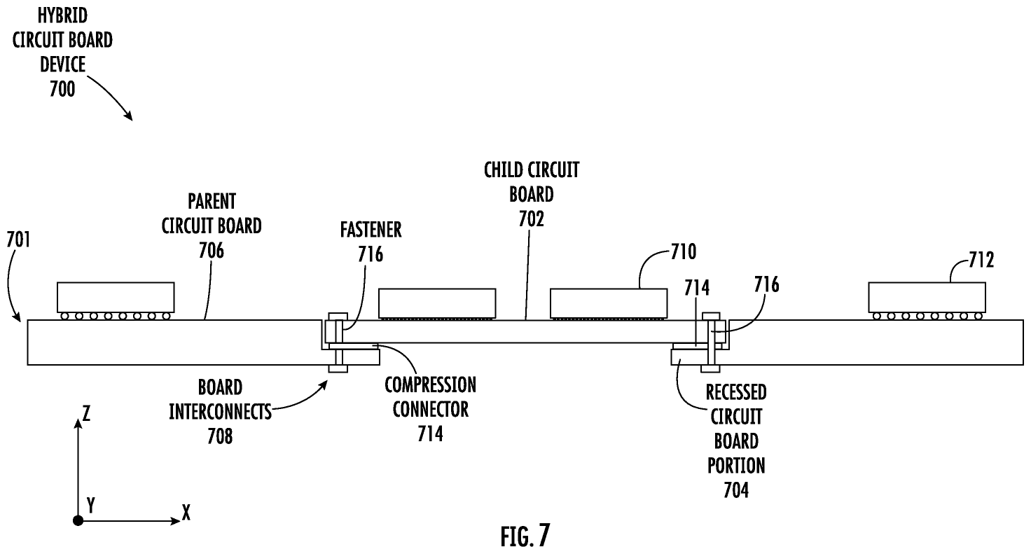

FIG. 7 is a cross-sectional side view of another hybrid circuit board device 700, including a hybrid circuit board 701, which includes a child circuit board 702 coupled in a recessed circuit board portion 704 of a parent circuit board 706. FIG. 7 is provided to show another example of board interconnects 708 that may be used to couple, mechanically and/or electrically, the child circuit board 702 to the parent circuit board 706. The hybrid circuit board device 700 also includes a first IC component 710 coupled to the child circuit board 702 and a second IC component 712 coupled to the parent circuit board 706. The board interconnect 708 electrically couples the child circuit board 702 to the parent circuit board 706. In this manner, the board interconnects 708 electrically couples the first IC component 710 on the parent circuit board 706 to the second IC component 712 on the child circuit board 702.

In this example, the board interconnects 708 comprise compression connectors 714 and fasteners 716. The compression connectors 714 may electrically couple the child circuit board 702 to the recessed circuit board portion 704, and the fasteners 716 mechanically couple the child circuit board 702 to the recessed circuit board portion 704, squeezing the compression connectors 714 between the child circuit board 702 and the parent circuit board 706 to maintain an electrical contact therebetween. The fasteners 716 include a bolt-type fastener, which may include opposing ends (e.g., head-end and nut-end) that may affect a total thickness of the hybrid circuit board device 700.

It should be understood that other types of board interconnects for mechanically and/or electrically coupling the child circuit board to the recessed circuit board portion are within the scope of the hybrid circuit boards disclosed herein. The board interconnects disclosed above each accommodate movement and/or stress between the child circuit boards and the recessed circuit board portions, which may be caused by expansion and contraction in response to heating and cooling.

According to aspects disclosed herein, a hybrid circuit board may be provided in or integrated into any processor-based device. Examples, without limitation, include a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

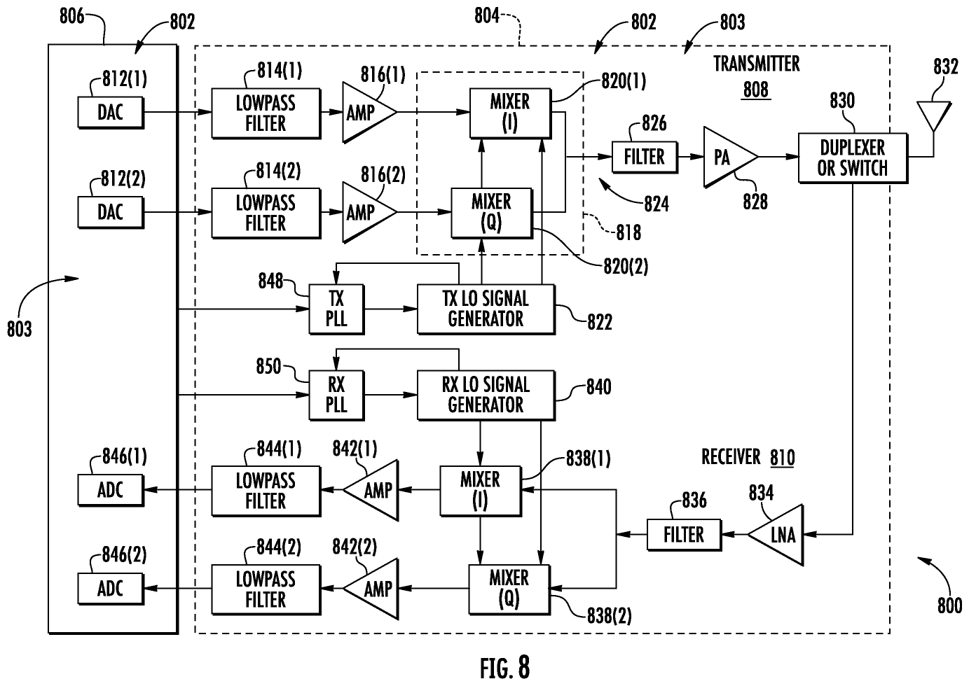

FIG. 8 illustrates an exemplary wireless communications device 800 that includes radio-frequency (RF) components formed from one or more integrated circuits (ICs) 802 and can include a hybrid circuit board device including a hybrid circuit board having a child circuit board disposed on a recessed circuit board portion of a parent circuit board as illustrated in FIGS. 1, 2, 4, 6, and 7, and according to any of the aspects disclosed herein. The wireless communications device 800 may include or be provided in any of the above-referenced devices as examples. As shown in FIG. 8, the wireless communications device 800 includes a transceiver 804 and a data processor 806. The data processor 806 may include a memory to store data and program codes. The transceiver 804 includes a transmitter 808 and a receiver 810 that support bi-directional communications. In general, the wireless communications device 800 may include any number of transmitters 808 and/or receivers 810 for any number of communication systems and frequency bands. All or a portion of the transceiver 804 may be implemented on one or more analog ICs, RFICs, mixed-signal ICs, etc.

The transmitter 808 or the receiver 810 may be implemented with a super-heterodyne architecture or a direct-conversion architecture. In the super-heterodyne architecture, a signal is frequency-converted between RF and baseband in multiple stages, e.g., from RF to an intermediate frequency (IF) in one stage and then from IF to baseband in another stage. In the direct-conversion architecture, a signal is frequency-converted between RF and baseband in one stage. The super-heterodyne and direct-conversion architectures may use different circuit blocks and/or have different requirements. In the wireless communications device 800 in FIG. 8, the transmitter 808 and the receiver 810 are implemented with the direct-conversion architecture.

In the transmit path, the data processor 806 processes data to be transmitted and provides I and Q analog output signals to the transmitter 808. In the exemplary wireless communications device 800, the data processor 806 includes digital-to-analog converters (DACs) 812(1), 812(2) for converting digital signals generated by the data processor 806 into the I and Q analog output signals, e.g., I and Q output currents, for further processing.

Within the transmitter 808, lowpass filters 814(1), 814(2) filter the I and Q analog output signals, respectively, to remove undesired signals caused by the prior digital-to-analog conversion. Amplifiers (AMPs) 816(1), 816(2) amplify the signals from the lowpass filters 814(1), 814(2), respectively, and provide I and Q baseband signals. An upconverter 818 upconverts the I and Q baseband signals with I and Q transmit (TX) local oscillator (LO) signals from a TX LO signal generator 822 through mixers 820(1), 820(2) to provide an upconverted signal 824. A filter 826 filters the upconverted signal 824 to remove undesired signals caused by the frequency upconversion as well as noise in a receive frequency band. A power amplifier (PA) 828 amplifies the upconverted signal 824 from the filter 826 to obtain the desired output power level and provides a transmit RF signal. The transmit RF signal is routed through a duplexer or switch 830 and transmitted via an antenna 832.

In the receive path, the antenna 832 receives signals transmitted by base stations and provides a received RF signal, which is routed through the duplexer or switch 830 and provided to a low noise amplifier (LNA) 834. The duplexer or switch 830 is designed to operate with a specific receive (RX)-to-TX duplexer frequency separation, such that RX signals are isolated from TX signals. The received RF signal is amplified by the LNA 834 and filtered by a filter 836 to obtain a desired RF input signal. Down conversion mixers 838(1), 838(2) mix the output of the filter 836 with I and Q RX LO signals (i.e., LO_I and LO_Q) from an RX LO signal generator 840 to generate I and Q baseband signals. The I and Q baseband signals are amplified by AMPs 842(1), 842(2) and further filtered by lowpass filters 844(1), 844(2) to obtain I and Q analog input signals, which are provided to the data processor 806. In this example, the data processor 806 includes analog-to-digital converters (ADCs) 846(1), 846(2) for converting the analog input signals into digital signals to be further processed by the data processor 806.

In the wireless communications device 800 of FIG. 8, the TX LO signal generator 822 generates the I and Q TX LO signals used for frequency upconversion, while the RX LO signal generator 840 generates the I and Q RX LO signals used for frequency down conversion. Each LO signal is a periodic signal with a particular fundamental frequency. A TX phase-locked loop (PLL) circuit 848 receives timing information from the data processor 806 and generates a control signal used to adjust the frequency and/or phase of the TX LO signals from the TX LO signal generator 822. Similarly, an RX PLL circuit 850 receives timing information from the data processor 806 and generates a control signal used to adjust the frequency and/or phase of the RX LO signals from the RX LO signal generator 840.

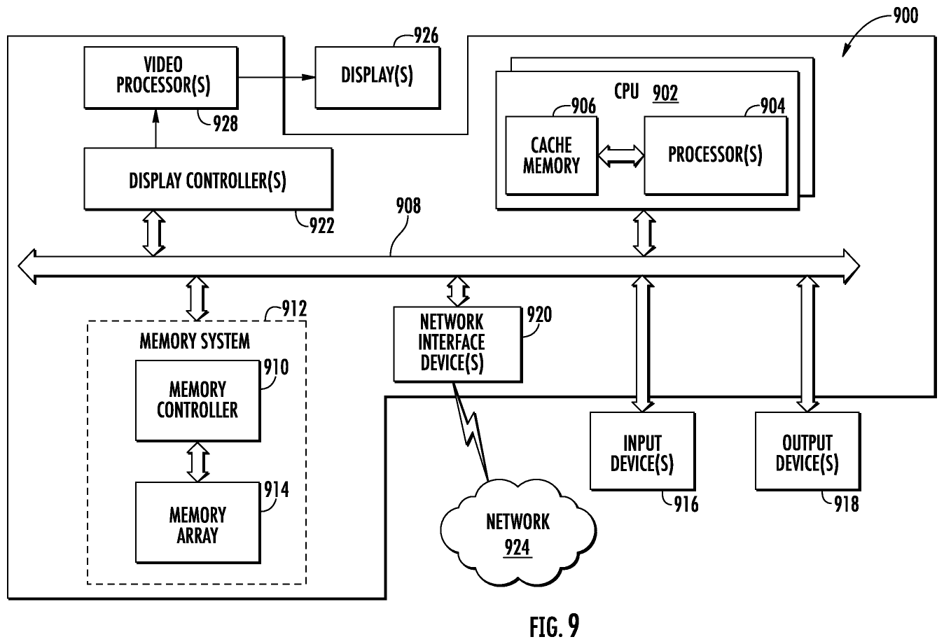

FIG. 9 illustrates an example of a processor-based system 900 that may be included on or may include an exemplary hybrid circuit board device including a hybrid circuit board, which includes a child circuit board disposed on a recessed circuit board portion of a parent circuit board, as illustrated in FIGS. 1, 2, 4, 6, and 7, according to any aspects disclosed herein. In this example, the processor-based system 900 includes one or more central processor units (CPUs) 902, which may also be referred to as CPUs or processor cores, each including one or more processors 904. The CPU(s) 902 may have cache memory 906 coupled to the processor(s) 904 for rapid access to temporarily stored data. The CPU(s) 902 is coupled to a system bus 908 and can intercouple master and slave devices included in the processor-based system 900. As is well known, the CPU(s) 902 communicates with these other devices by exchanging address, control, and data information over the system bus 908. For example, the CPU(s) 902 can communicate bus transaction requests to a memory controller 910 as an example of a slave device. Although not illustrated in FIG. 9, multiple system buses 908 could be provided; wherein each system bus 908 constitutes a different fabric.

Other master and slave devices can be connected to the system bus 908. As illustrated in FIG. 9, these devices can include a memory system 912 that includes the memory controller 910 and one or more memory arrays 914, one or more input devices 916, one or more output devices 918, one or more network interface devices 920, and one or more display controllers 922, as examples. The input device(s) 916 can include any type of input device, including, but not limited to, input keys, switches, voice processors, etc. The output device(s) 918 can include any type of output device, including, but not limited to, audio, video, other visual indicators, etc. The network interface device(s) 920 can be any device configured to allow an exchange of data to and from a network 924. The network 924 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 920 can be configured to support any type of communications protocol desired.

The CPU(s) 902 may also be configured to access the display controller(s) 922 over the system bus 908 to control information sent to one or more displays 926. The display controller(s) 922 sends information to the display(s) 926 to be displayed via one or more video processors 928, which process the information to be displayed into a format suitable for the display(s) 926. The display(s) 926 can include any type of display, including, but not limited to, a cathode ray tube (CRT), a liquid crystal display (LCD), a plasma display, or a light-emitting diode (LED) display, etc.

Those of skill in the art will further appreciate that the various illustrative logical blocks, modules, circuits, and algorithms described in connection with the aspects disclosed herein may be implemented as electronic hardware, instructions stored in memory or another computer-readable medium and executed by a processor or other processing device, or combinations of both. As examples, the master and slave devices described herein may be employed in any circuit, hardware component, IC, or IC chip. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware and may reside, for example, in Random Access Memory (RAM), flash memory, Read-Only Memory (ROM), Electrically Programmable ROM (EPROM), Electrically Erasable Programmable ROM (EEPROM), registers, a hard disk, a removable disk, a CD-ROM, or any other form of computer-readable medium known in the art. An exemplary storage medium is coupled to the processor such that the processor can read information from and write information to the storage medium. In the alternative, the storage medium may be integral to the processor. The processor and the storage medium may reside in an ASIC. The ASIC may reside in a remote station. Alternatively, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in several different steps. Additionally, one or more operational steps discussed in the exemplary aspects may be combined. It is to be understood that the operational steps illustrated in the flowchart diagrams may be subject to numerous different modifications, as will be readily apparent to one of skill in the art. Those of skill in the art will also understand that information and signals may be represented using various technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

Implementation examples are described in the following numbered clauses:
1. A hybrid circuit board device comprising:
   a hybrid circuit board comprising:
      a first circuit board comprising:
         a first circuit board portion having a first thickness in a thickness direction and comprising first interconnects configured to couple to a first integrated circuit (IC) component; and
         a recessed circuit board portion having a second thickness thinner than the first thickness in the thickness direction;
      a second circuit board having a third thickness in the thickness direction and disposed on the recessed circuit board portion, the second circuit board comprising second interconnects configured to couple to a second IC component; and
      at least one board interconnect coupling the second circuit board to the recessed circuit board portion of the first circuit board.
2. The hybrid circuit board device of clause 1, wherein:
   the first interconnects are of a first interconnect type;
   the second interconnects are of a second intertype; and
   the first interconnects comprise a different center-to-center pitch than the second interconnects.
3. The hybrid circuit board device of clause 1, wherein:
   the first interconnects are of a first interconnect type;
   the second interconnects are of a second interconnect type; and
   the first interconnects have a same center-to-center pitch as the second interconnects.
4. The hybrid circuit board device of any one of clause 1 to clause 3, further comprising:
   a first IC component coupled to the first interconnects of the first circuit board; and
   a second IC component coupled to the second interconnects of the second circuit board.
5. The hybrid circuit board device of clause 1 any one of clause 1 to clause 4, wherein the at least one board interconnect is between the second circuit board and the recessed circuit board portion and mechanically couples the second circuit board to the first circuit board.
6. The hybrid circuit board device of any one of clause 1 to clause 5, wherein the at least one board interconnect electrically couples the second circuit board to the first circuit board.
7. The hybrid circuit board device of any one of any one of clause 1 to clause 6, wherein the at least one board interconnect comprises an adhesive.
8 The hybrid circuit board device of clause 1 to clause 6, wherein the at least one board interconnect comprises a solder bump.
9. The hybrid circuit board device of clause 1 to clause 6, wherein the at least one board interconnect comprises a compression connector.
10. The hybrid circuit board device of clause 1 to clause 9, wherein the second thickness is less than fifty percent (50%) of the first thickness.
11. The hybrid circuit board device of clause 1 to clause 10, wherein a combined thickness of the second thickness of the recessed circuit board portion and the third thickness of the second circuit board is less than or equal to the first thickness of the first circuit board portion.
12. The hybrid circuit board device of clause 1 to clause 11, wherein:
   the first interconnects are disposed on a first surface of the first circuit board portion;
   the first circuit board further comprises a first back side surface opposite to the first surface;
   the first surface and the first back side surface are separated in the thickness direction by the first thickness;
   the second interconnects are disposed on a second surface of the second circuit board;
   the second circuit board comprises a second back side surface opposite to the second surface;
   the second surface and the second back side surface are separated in the thickness direction by the third thickness;
   the recessed circuit board portion comprises the first back side surface of the first circuit board and a recessed surface opposite to the first back side surface; and
   the first back side surface and the recessed surface are separated in the thickness direction by the second thickness.
13. The hybrid circuit board device of clause 12, wherein:
   the second back side surface of the second circuit board and the recessed surface of the recessed circuit board portion are each orthogonal to the thickness direction; and
   the second back side surface of the second circuit board overlaps the recessed surface of the recessed circuit board portion in the thickness direction.
14. The hybrid circuit board device of clause 1 to clause 13, wherein:
   the first circuit board comprises a shoulder boundary between the first circuit board portion and the recessed circuit board portion; and
   the recessed surface extends from the shoulder boundary.
15. The hybrid circuit board device of clause 14, wherein the shoulder boundary comprises a first linear boundary section.
16. The hybrid circuit board device of clause 14 or clause 15, wherein the shoulder boundary comprises a second linear boundary section.
17. The hybrid circuit board device of clause 16, wherein the second linear boundary section is orthogonal to the first linear boundary section.
18. The hybrid circuit board device of any of clause 15 to clause 17, wherein the shoulder boundary comprises a third linear boundary section orthogonal to the first linear boundary section.
19. The hybrid circuit board device of any of clause 15 to clause 18, wherein:
   an overlapping edge portion of the second back side surface of the second circuit board overlaps the recessed surface in the first linear boundary section; and
   a non-overlapping portion of the second back side surface does not overlap the recessed surface.
20. The hybrid circuit board device of any of clause 15 to clause 19, wherein:
   the first circuit board comprises an opening extending in the thickness direction through the recessed circuit board portion; and
   the shoulder boundary extends around the opening.
21 The hybrid circuit board device of clause 20, wherein:
   the opening comprises a rectangular shape in the recessed surface;
   the shoulder boundary comprises a rectangular boundary; and
   overlapping edge portions of the second back side surface along a first perimeter of the second circuit board overlap the recessed surface around a second perimeter of the opening.
22. The hybrid circuit board device of any of clause 1 to clause 21 integrated into a device selected from the group consisting of: a set-top box; an entertainment unit; a navigation device; a communications device; a fixed location data unit; a mobile location data unit; a global positioning system (GPS) device; a mobile phone; a cellular phone; a smartphone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.
23. A method of fabricating a hybrid circuit board device, the method comprising:
   forming a hybrid circuit board, comprising:
      forming a first circuit board comprising:
         a first circuit board portion having a first thickness in a thickness direction and comprising first interconnects configured to couple to a first integrated circuit (IC) component; and
         a recessed circuit board portion having a second thickness thinner than the first thickness in the thickness direction;
      forming a second circuit board having a third thickness in the thickness direction and disposed on the recessed circuit board portion, the second circuit board comprising second interconnects configured to couple to a second IC component; and
      forming at least one board interconnect between the second circuit board and the recessed circuit board portion of the first circuit board.
24. The method of clause 23, further comprising, before disposing the second circuit board on the recessed circuit board portion:
   coupling the second IC component to the second interconnects; and
   coupling the first IC components to the first interconnects.
25. The method of clause 23, further comprising after disposing the second circuit board on the recessed circuit board portion:
   coupling the second IC component to the second interconnects; and
   coupling the first IC components to the first interconnects.
26. The method of any one of clause 23 to clause 25, further comprising, employing solder balls to couple the second circuit board to the recessed circuit board region.
27. The method of any one of clause 23 to clause 25, further comprising, employing compression connectors to couple the second circuit board to the recessed circuit board region.
28. The method of any one of clause 23 to clause 25, further comprising, employing adhesive to couple the second circuit board to the recessed circuit board region.

What is claimed is:

1. A hybrid circuit board device comprising:
a hybrid circuit board comprising:
a first circuit board comprising:
a first circuit board portion having a first thickness in a thickness direction and comprising first interconnects configured to couple to a first integrated circuit (IC) component; and
a recessed circuit board portion having a second thickness thinner than the first thickness in the thickness direction;
a second circuit board having a third thickness in the thickness direction and disposed on the recessed circuit board portion, the second circuit board comprising second interconnects configured to couple to a second IC component; and
at least one board interconnect coupling the second circuit board to the recessed circuit board portion of the first circuit board.

2. The hybrid circuit board device of claim 1, wherein:
the first interconnects are of a first interconnect type;
the second interconnects are of a second intertype; and
the first interconnects comprise a different center-to-center pitch than the second interconnects.

3. The hybrid circuit board device of claim 1, wherein:
the first interconnects are of a first interconnect type;
the second interconnects are of a second interconnect type; and
the first interconnects have a same center-to-center pitch as the second interconnects.

4. The hybrid circuit board device of claim 1, further comprising:
a first IC component coupled to the first interconnects of the first circuit board; and
a second IC component coupled to the second interconnects of the second circuit board.

5. The hybrid circuit board device of claim 1, wherein the at least one board interconnect is between the second circuit board and the recessed circuit board portion and mechanically couples the second circuit board to the first circuit board.

6. The hybrid circuit board device of claim 1, wherein the at least one board interconnect electrically couples the second circuit board to the first circuit board.

7. The hybrid circuit board device of claim 5, wherein the at least one board interconnect comprises an adhesive.

8. The hybrid circuit board device of claim 1, wherein the at least one board interconnect comprises a solder bump.

9. The hybrid circuit board device of claim 1, wherein the at least one board interconnect comprises a compression connector.

10. The hybrid circuit board device of claim 1, wherein the second thickness is less than fifty percent (50%) of the first thickness.

11. The hybrid circuit board device of claim 1, wherein a combined thickness of the second thickness of the recessed circuit board portion and the third thickness of the second circuit board is less than or equal to the first thickness of the first circuit board portion.

12. The hybrid circuit board device of claim 1, wherein:
the first interconnects are disposed on a first surface of the first circuit board portion;
the first circuit board further comprises a first back side surface opposite to the first surface;
the first surface and the first back side surface are separated in the thickness direction by the first thickness;
the second interconnects are disposed on a second surface of the second circuit board;
the second circuit board comprises a second back side surface opposite to the second surface;
the second surface and the second back side surface are separated in the thickness direction by the third thickness;
the recessed circuit board portion comprises the first back side surface of the first circuit board and a recessed surface opposite to the first back side surface; and
the first back side surface and the recessed surface are separated in the thickness direction by the second thickness.

13. The hybrid circuit board device of claim 12, wherein:
the second back side surface of the second circuit board and the recessed surface of the recessed circuit board portion are each orthogonal to the thickness direction; and
the second back side surface of the second circuit board overlaps the recessed surface of the recessed circuit board portion in the thickness direction.

14. The hybrid circuit board device of claim 12, wherein:
the first circuit board comprises a shoulder boundary between the first circuit board portion and the recessed circuit board portion; and
the recessed surface extends from the shoulder boundary.

15. The hybrid circuit board device of claim 14, wherein the shoulder boundary comprises a first linear boundary section.

16. The hybrid circuit board device of claim 15, wherein the shoulder boundary comprises a second linear boundary section.

17. The hybrid circuit board device of claim 16, wherein the second linear boundary section is orthogonal to the first linear boundary section.

18. The hybrid circuit board device of claim 16, wherein the shoulder boundary comprises a third linear boundary section orthogonal to the first linear boundary section.

19. The hybrid circuit board device of claim 15, wherein:
an overlapping edge portion of the second back side surface of the second circuit board overlaps the recessed surface in the first linear boundary section; and
a non-overlapping portion of the second back side surface does not overlap the recessed surface.

20. The hybrid circuit board device of claim 14, wherein:
the first circuit board comprises an opening extending in the thickness direction through the recessed circuit board portion; and
the shoulder boundary extends around the opening.

21. The hybrid circuit board device of claim 20, wherein:
the opening comprises a rectangular shape in the recessed surface;
the shoulder boundary comprises a rectangular boundary; and
overlapping edge portions of the second back side surface along a first perimeter of the second circuit board overlap the recessed surface around a second perimeter of the opening.

22. The hybrid circuit board device of claim 1 integrated into a device selected from the group consisting of: a set-top box; an entertainment unit; a navigation device; a communications device; a fixed location data unit; a mobile location data unit; a global positioning system (GPS) device; a mobile phone; a cellular phone; a smartphone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

23. A method of fabricating a hybrid circuit board device, the method comprising:
forming a hybrid circuit board, comprising:
forming a first circuit board comprising:
a first circuit board portion having a first thickness in a thickness direction and comprising first interconnects configured to couple to a first integrated circuit (IC) component; and
a recessed circuit board portion having a second thickness thinner than the first thickness in the thickness direction;
forming a second circuit board having a third thickness in the thickness direction and disposed on the recessed circuit board portion, the second circuit board comprising second interconnects configured to couple to a second IC component; and
forming at least one board interconnect between the second circuit board and the recessed circuit board portion of the first circuit board.

24. The method of claim 23, further comprising, before disposing the second circuit board on the recessed circuit board portion:
coupling the second IC component to the second interconnects; and
coupling the first IC components to the first interconnects.

25. The method of claim 23, further comprising after disposing the second circuit board on the recessed circuit board portion:
coupling the second IC component to the second interconnects; and
coupling the first IC components to the first interconnects.

26. The method of claim 23, further comprising, employing solder balls to couple the second circuit board to the recessed circuit board region.

27. The method of claim 23, further comprising, employing compression connectors to couple the second circuit board to the recessed circuit board region.

28. The method of claim 23, further comprising, employing adhesive to couple the second circuit board to the recessed circuit board region.
